(19) United States
(12) Patent Application Publication
(10) Pub. No.: US 2025/0274085 A1
(43) Pub. Date: Aug. 28, 2025

(54) HIGH FREQUENCY CIRCUIT AND AMPLIFIER CIRCUIT

(71) Applicant: Murata Manufacturing Co., Ltd., Kyoto (JP)

(72) Inventors: Kenji TAHARA, Kyoto (JP); Kae YAMAMOTO, Kyoto (JP)

(21) Appl. No.: 19/201,340

(22) Filed: May 7, 2025

Related U.S. Application Data
(63) Continuation of application No. PCT/JP2023/025481, filed on Jul. 10, 2023.

(30) Foreign Application Priority Data
Nov. 11, 2022 (JP) 2022-180848

(51) Int. Cl. H03F 1/32; H03F 1/02; H03F 3/24

(52) U.S. Cl. CPC H03F 1/3282; H03F 1/0222; H03F 3/245; H03F 2200/102

(57) ABSTRACT

A high frequency circuit includes power amplifiers that amplify high frequency signals, a tracker circuit that is configured to output a variable power supply voltage, a phase shift circuit that is connected to an input end of the power amplifier and is configured to vary a phase of a high frequency signal, a phase shift circuit that is connected to an input end of the power amplifier and is configured to vary a phase of a high frequency signal, an array antenna including an antenna that is connected to an output end of the power amplifier and an antenna that is connected to an output end of the power amplifier, first and second delay circuits each of which is connected between the tracker circuit and the power amplifier and is configured to vary a delay time of the variable power supply voltage.

### CROSS REFERENCE TO RELATED APPLICATION

This is a continuation of International Application No. PCT/JP2023/025481 filed on Jul. 10, 2023 which claims priority from Japanese Patent Application No. 2022-180848 filed on Nov. 11, 2022. The contents of these applications are incorporated herein by reference in their entireties.

### BACKGROUND OF THE DISCLOSURE

### Field of the Disclosure

The present disclosure relates to a high frequency circuit and an amplifier circuit.

### Description of the Related Art

In recent years, efficiency (power added efficiency) has been improved by applying envelope tracking (ET) to a power amplifier circuit.

In U.S. Patent Application Publication No. 2021/0281219, a power amplifier device to which a variable power supply voltage is supplied using ET is disclosed. The power amplifier device includes a power amplifier, a phase modulation circuit that is arranged at an input stage of the power amplifier and is necessary for beamforming of high frequency signals, and an amplitude modulation circuit for amplitude adjustment of the variable power supply voltage.

### BRIEF SUMMARY OF THE DISCLOSURE

However, in the case of the power amplifier device disclosed in U.S. Patent Application Publication No. 2021/0281219, there is a possibility that the variable power supply voltage does not sufficiently support a high frequency signal inputted to the power amplifier and linearity is degraded due to degradation of error vector magnitude (EVM) and adjacent channel leakage power ratio (ACLR) of a high frequency signal outputted from the power amplifier device.

Accordingly, the present disclosure provides a high frequency circuit and an amplifier circuit in which degradation of linearity is suppressed.

In order to achieve the possible benefit mentioned above, a high frequency circuit according to an aspect of the present disclosure includes a first power amplifier and a second power amplifier that amplify high frequency signals, a tracker circuit that is configured to output a variable power supply voltage, a first variable phase shift circuit that is connected to an input end of the first power amplifier and is configured to vary a phase of a high frequency signal, a second variable phase shift circuit that is connected to an input end of the second power amplifier and is configured to vary a phase of a high frequency signal, an array antenna including a first antenna that is connected to an output end of the first power amplifier and a second antenna that is connected to an output end of the second power amplifier, a first variable delay circuit that is connected between the tracker circuit and the first power amplifier and is configured to vary a delay amount of the variable power supply voltage, and a second variable delay circuit that is connected between the tracker circuit and the second power amplifier and is configured to vary a delay amount of the variable power supply voltage.

Furthermore, a high frequency circuit according to an aspect of the present disclosure includes a first power amplifier and a second power amplifier to which a variable power supply voltage is applied, a first variable phase shift circuit that is configured to vary, based on a first phase shift amount, a phase of a high frequency signal inputted to the first power amplifier, a second variable phase shift circuit that is configured to vary, based on a second phase shift amount, a phase of a high frequency signal inputted to the second power amplifier, an array antenna including a first antenna that radiates a high frequency signal outputted from the first power amplifier and a second antenna that radiates a high frequency signal outputted from the second power amplifier, a first variable delay circuit that is configured to add a first delay amount corresponding to the first phase shift amount to the variable power supply voltage to be applied to the first power amplifier, and a second variable delay circuit that is configured to add a second delay amount corresponding to the second phase shift amount to the variable power supply voltage to be applied to the second power amplifier.

Furthermore, an amplifier circuit according to an aspect of the present disclosure includes a first power amplifier and a second power amplifier that amplify high frequency signals, an external connection terminal that receives a variable power supply voltage corresponding to a high frequency signal, a first variable phase shift circuit that is connected to an input end of the first power amplifier and is configured to vary a phase of a high frequency signal, a second variable phase shift circuit that is connected to an input end of the second power amplifier and is configured to vary a phase of a high frequency signal, a first variable delay circuit that is connected between the external connection terminal and the first power amplifier and is configured to vary a delay time of the variable power supply voltage, and a second variable delay circuit that is connected between the external connection terminal and the second power amplifier and is configured to vary a delay time of the variable power supply voltage.

According to the present disclosure, a high frequency circuit and an amplifier circuit in which degradation of linearity is suppressed can be provided.

### BRIEF DESCRIPTION OF THE SEVERAL VIEWS OF THE DRAWINGS

FIG. 1A is a graph indicating an example of transition of a power supply voltage in an analog envelope tracking mode.

FIG. 1B is a graph indicating an example of transition of a power supply voltage in a digital envelope tracking mode.

FIG. 2 is a circuit configuration diagram of a high frequency circuit according to an embodiment.

FIG. 3 is a circuit diagram illustrating an example of a delay circuit and a peripheral circuit thereof in the embodiment.

FIG. 4 is a diagram illustrating a relationship between an antenna arrangement and a beam radiation direction in the high frequency circuit according to the embodiment.

FIG. 5A includes diagrams illustrating relationships between high frequency signals and a variable power supply voltage inputted and outputted to and from an amplifier circuit according to the embodiment.

FIG. 5B includes diagrams illustrating relationships between high frequency signals and a variable power supply voltage inputted and outputted to and from an amplifier circuit according to a comparative example.

### DETAILED DESCRIPTION OF THE DISCLOSURE

Hereinafter, embodiments of the present disclosure will be described in detail with reference to the drawings. The embodiments described below each illustrate a comprehensive or specific example. Numerical values, shapes, materials, component elements, arrangements of the component elements, manners in which the component elements are connected, and so on illustrated in the embodiments described below are merely examples and are not intended to limit the present disclosure.

The drawings are schematic diagrams in which emphasis, omission, or ratio adjustment is performed in an appropriate manner in order that the present disclosure is illustrated. The drawings are not necessarily illustrated precisely and may differ from actual shapes, positional relationships, and ratios. In the drawings, substantially the same configurations are denoted by the same reference signs, and repetitive description may be omitted or simplified.

In a circuit configuration in the present disclosure, “being connected” not only represents being directly connected by a connection terminal and/or a wiring conductor but also includes being electrically connected with another circuit element interposed therebetween. “Being connected between A and B” represents being connected between A and B and to both A and B.

Furthermore, in the present disclosure, a “signal path” represents a transmission line including a wire through which a high frequency signal propagates, an electrode directly connected to the wire, a terminal directly connected to the wire or the electrode, and the like.

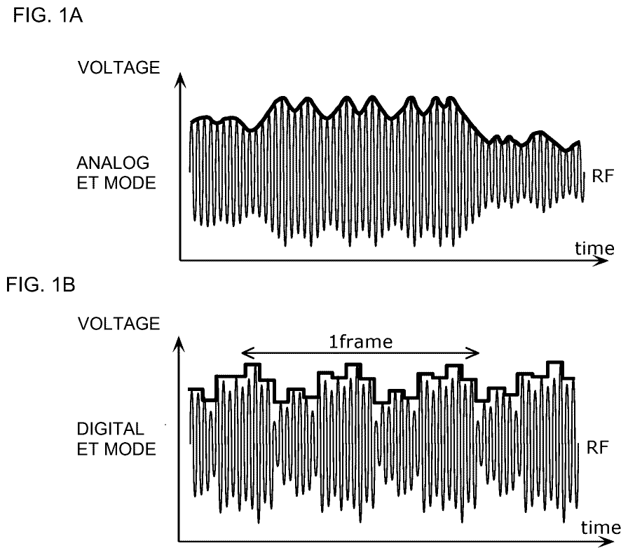

First, as a technique for amplifying a high frequency signal highly efficiently, tracking modes in which a variable power supply voltage that is dynamically adjusted with time on the basis of the high frequency signal is supplied to a power amplifier will be explained. The tracking modes are modes for dynamically adjusting a power supply voltage to be applied to an amplifier circuit. There are some types of tracking modes. An envelope tracking (ET) mode (including an analog ET mode and a digital ET mode) and a symbol power tracking (SPT) will be explained below with reference to FIGS. 1A and 1B. In each of FIGS. 1A and 1B, the horizontal axis represents time and the vertical axis represents voltage. The thick solid line represents a power supply voltage and the thin solid line (waveform) represents a modulated wave.

FIG. 1A is a graph indicating an example of transition of a power supply voltage in the analog ET mode. The analog ET mode is an example of an ET mode. As illustrated in FIG. 1A, in the analog ET mode, a power supply voltage is continuously varied so that an envelope of a modulated wave can be tracked. In the analog ET mode, the power supply voltage is determined based on an envelope signal.

An envelope signal is a signal indicating an envelope of a modulated wave. An envelope value is expressed by, for example, the square root of (I²+Q²), where (I, Q) represents a constellation point. The constellation point is a point representing, on a constellation diagram, a signal modulated by digital modulation. (I, Q) is determined, for example, based on transmission information, by a baseband integrated circuit (BBIC).

FIG. 1B is a graph indicating an example of transition of a power supply voltage in the digital ET mode. As illustrated in FIG. 1B, in the digital ET mode, a power supply voltage is varied to a plurality of discrete voltage levels in one frame so that an envelope of a modulated wave can be tracked. As a result, a power supply voltage signal forms a rectangular wave. In the digital ET mode, the level of a power supply voltage is selected or set, based on an envelope signal, from among the plurality of discrete voltage levels.

Furthermore, although not illustrated in the drawing, in the SPT mode, a power supply voltage is varied symbol by symbol, which is smaller than one frame, on the basis of an average output power.

A frame for the case where a subcarrier spacing is, for example, 15 kHz is a unit of a high frequency signal with a length of 10 milliseconds and includes ten subframes. A subframe is a unit of a high frequency signal with a length of 1 millisecond and includes two slots. A slot is a unit of a high frequency signal with a length of 0.5 milliseconds and includes six or seven symbols. A symbol is a unit of a high frequency signal with a length of, for example, 71 microseconds and includes a cyclic prefix (CP).

In the SPT mode, the level of a power supply voltage is modulated in units of one symbol. At this time, the voltage level is changed in a section of a CP. For example, in the first symbol, the voltage level is changed to a higher voltage level in a CP. In the second symbol, the voltage level is changed to a lower voltage level in a CP. In a subsequent symbol, the voltage level is not necessarily changed. The level of a power supply voltage can be modulated based on a data signal in each symbol section.

### Embodiment

### 1 Configuration of High Frequency Circuit 5

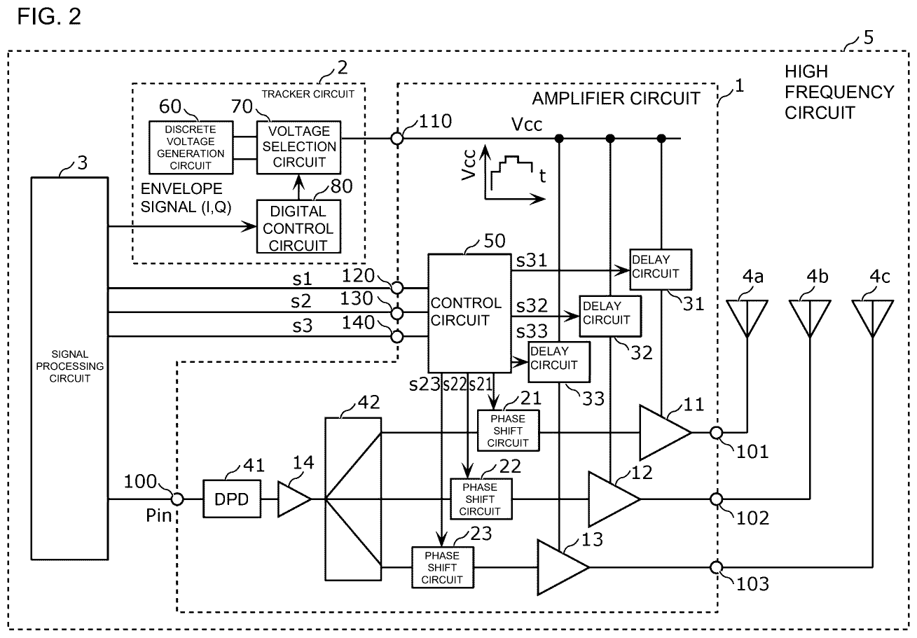

A high frequency circuit 5 according to an embodiment will be described with reference to FIG. 2.

FIG. 2 is a circuit configuration diagram of the high frequency circuit 5 according to the embodiment. The high frequency circuit 5 according to the embodiment corresponds to a user terminal (user equipment: UE) in a cellular network and is typically a cellular phone, a smartphone, a tablet computer, a wearable device, or the like. The high frequency circuit 5 may be an Internet of things (IoT) sensor/device, a medical/healthcare device, a vehicle, an unmanned aerial vehicle (UAV) (a so-called drone), or an automated guided vehicle (AGV).

The high frequency circuit 5 according to the embodiment includes an amplifier circuit 1, a tracker circuit 2, a signal processing circuit 3, and antennas 4a, 4b, and 4c.

The signal processing circuit 3 is an example of a signal processing circuit that processes a high frequency signal. The signal processing circuit 3 includes a controller that controls the amplifier circuit 1 and the tracker circuit 2. Specifically, the signal processing circuit 3 performs signal processing, by up-conversion or other processes, on a transmission signal and outputs a high frequency signal generated by the signal processing to the amplifier circuit 1. The signal processing circuit 3 also outputs an envelope signal, which is a signal indicating an envelope of a modulated wave of a high frequency signal, to the tracker circuit 2. Furthermore, the signal processing circuit 3 outputs to the amplifier circuit 1 beam control signals s1, s2, and s3 indicating a radiation direction of an output beam of high frequency signals outputted from the antennas 4a to 4c.

Part of or the entire function of the controller of the signal processing circuit 3 may be implemented outside the signal processing circuit 3, for example, in the amplifier circuit 1 and the tracker circuit 2.

The tracker circuit 2 is configured to output a variable power supply voltage Vcc based on a tracking mode to the amplifier circuit 1. As tracking modes, the analog ET mode, the digital ET mode, and the SPT mode can be used. FIG. 2 illustrates a circuit configuration for outputting a plurality of discrete variable power supply voltages in the case where the digital ET mode is applied. In the case where the digital ET mode is applied, the tracker circuit 2 includes a discrete voltage generation circuit 60, a voltage selection circuit 70, and a digital control circuit 80.

The discrete voltage generation circuit 60 is configured to generate a plurality of discrete voltages having discrete voltage levels. The discrete voltage generation circuit 60 is, for example, a switched-capacitor circuit including a plurality of capacitors and a plurality of switches.

The voltage selection circuit 70 is configured to selectively output, based on an envelope signal, at least one of the plurality of discrete voltages generated by the discrete voltage generation circuit 60 to the amplifier circuit 1. The voltage selection circuit 70 is controlled on the basis of a digital control signal outputted from the digital control circuit 80. That is, in the case where the digital ET mode is applied, the tracker circuit 2 outputs a plurality of discrete variable power supply voltages based on envelope values of high frequency signals.

The digital control circuit 80 is capable of controlling, based on an envelope signal from the signal processing circuit 3, the voltage selection circuit 70. Specifically, the digital control circuit 80 generates, based on an envelope signal received from the signal processing circuit 3, a digital logic (digital control logic/line: DCL) signal.

The digital control circuit 80 is not necessarily included in the tracker circuit 2 but may be included in the signal processing circuit 3.

The antenna 4a is an example of a first antenna. The antenna 4a is connected to an output end of a power amplifier 11 with an antenna connection terminal 101 interposed therebetween and radiates a first high frequency signal outputted from the power amplifier 11. The antenna 4b is an example of a second antenna. The antenna 4b is connected to an output end of a power amplifier 12 with an antenna connection terminal 102 interposed therebetween and radiates a second high frequency signal outputted from the power amplifier 12. The antenna 4c is connected to an output end of a power amplifier 13 with an antenna connection terminal 103 interposed therebetween and radiates a third high frequency signal outputted from the power amplifier 13.

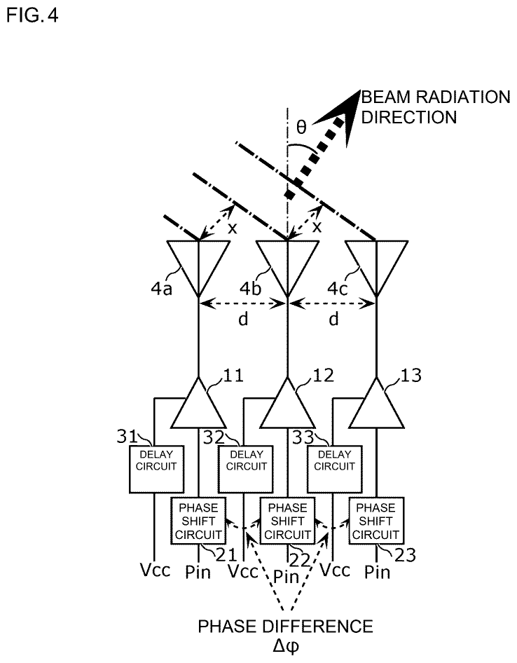

The antennas 4a to 4c configure an array antenna. For example, the antennas 4a to 4c are arranged in an equally spaced manner, and radiation surfaces of the antennas 4a to 4c are on the same plane. With the arrangement described above, the first high frequency signal, the second high frequency signal, and the third high frequency signal form one output beam (radiation beam) having a directivity. An arrangement configuration of the antennas 4a to 4c will be described later with reference to FIG. 4.

The array antenna included in the high frequency circuit 5 does not necessarily include the three antennas 4a to 4c but may include two or more antennas.

The amplifier circuit 1 includes the power amplifiers 11, 12, and 13, phase shift circuits 21, 22, and 23, delay circuits 31, 32, and 33, a DPD circuit 41, a preamplifier 14, a divider 42, a signal input terminal 100, the antenna connection terminals 101, 102, and 103, a power supply voltage terminal 110, and beam control terminals 120, 130, and 140.

The signal input terminal 100 is connected to the signal processing circuit 3, and a high frequency signal outputted from the signal processing circuit 3 is transmitted through the signal input terminal 100 to the phase shift circuits 21 to 23 and the power amplifiers 11 to 13.

The antenna connection terminal 101 is connected to the power amplifier 11 and the antenna 4a, and the first high frequency signal amplified by the power amplifier 11 is transmitted through the antenna connection terminal 101 to the antenna 4a. The antenna connection terminal 102 is connected to the power amplifier 12 and the antenna 4b, and the second high frequency signal amplified by the power amplifier 12 is transmitted through the antenna connection terminal 102 to the antenna 4b. The antenna connection terminal 103 is connected to the power amplifier 13 and the antenna 4c, and the third high frequency signal amplified by the power amplifier 13 is transmitted through the antenna connection terminal 103 to the antenna 4c.

The power supply voltage terminal 110 is an example of an external connection terminal of the amplifier circuit 1. The power supply voltage terminal 110 is connected to the tracker circuit 2, connected to the power amplifier 11 with the delay circuit 31 interposed therebetween, connected to the power amplifier 12 with the delay circuit 32 interposed therebetween, and connected to the power amplifier 13 with the delay circuit 33 interposed therebetween. With this connection arrangement, the variable power supply voltage Vcc generated by the tracker circuit 2 is transmitted through the power supply voltage terminal 110 to the power amplifiers 11 to 13. The amplifier circuit 1 receives through the power supply voltage terminal 110 a plurality of discrete variable power supply voltages from the tracker circuit 2.

The beam control signal s1 indicating a radiation direction of an output beam of high frequency signals to be formed by the antennas 4a to 4c is transmitted through the beam control terminal 120 to the amplifier circuit 1. The beam control signal s2 indicating a radiation direction of an output beam of high frequency signals to be formed by the antennas 4a to 4c is transmitted through the beam control terminal 130 to the amplifier circuit 1. The beam control signal s3 indicating a radiation direction of an output beam of high frequency signals to be formed by the antennas 4a to 4c is transmitted through the beam control terminal 140 to the amplifier circuit 1. The beam control signals outputted from the signal processing circuit 3 may be digital control signals. In the case where a beam control signal is a digital control signal, only one beam control signal may be outputted from the signal processing circuit 3. In this case, for example, two beam control terminals are provided.

The power amplifier 11 is an example of a first power amplifier and amplifies a high frequency signal inputted through the signal input terminal 100. An input end of the power amplifier 11 is connected to the phase shift circuit 21, the output end of the power amplifier 11 is connected to the antenna connection terminal 101, and a power supply input end of the power amplifier 11 is connected to the delay circuit 31.

The power amplifier 12 is an example of a second power amplifier and amplifies a high frequency signal inputted through the signal input terminal 100. An input end of the power amplifier 12 is connected to the phase shift circuit 22, the output end of the power amplifier 12 is connected to the antenna connection terminal 102, and a power supply input end of the power amplifier 12 is connected to the delay circuit 32.

The power amplifier 13 amplifies a high frequency signal inputted through the signal input terminal 100. An input end of the power amplifier 13 is connected to the phase shift circuit 23, the output end of the power amplifier 13 is connected to the antenna connection terminal 103, and a power supply input end of the power amplifier 13 is connected to the delay circuit 33.

Each of the power amplifiers 11 to 13 includes an amplifying transistor. The amplifying transistor is, for example, a bipolar transistor such as a heterojunction bipolar transistor (HBT) or a field effect transistor such as a metal-oxide-semiconductor field effect transistor (MOSFET).

Furthermore, each of the power amplifiers 11 to 13 may include two amplifying transistors that are cascode-connected. Since each of the power amplifiers 11 to 13 has a configuration of cascode connection, a high amplification gain can be ensured also for high frequency signals in a millimeter-wave band and a sub-terahertz band in the amplifier circuit 1.

The DPD circuit 41 is connected to the signal input terminal 100 and has a function for, in order to improve linearity of high frequency signals to be outputted from the power amplifiers 11 to 13, performing in advance amplitude-amplitude conversion and/or amplitude-phase conversion on a signal outputted from the signal processing circuit 3 so that the high frequency signal includes a distortion component. Thus, signal distortion characteristics of the power amplifiers 11 to 13 and a distortion component of the high frequency signal generated by the DPD circuit 41 are balanced out, and the linearity of the high frequency signals to be outputted from the power amplifiers 11 to 13 can thus be improved.

An input end of the preamplifier 14 is connected to the DPD circuit 41, and an output end of the preamplifier 14 is connected to the divider 42. The preamplifier 14 amplifies a high frequency signal outputted from the DPD circuit 41.

The divider 42 performs power distribution of a high frequency signal outputted from the preamplifier 14 to divide the high frequency signal into three high frequency signals, and outputs the three high frequency signals to the phase shift circuits 21 to 23.

At least one of the DPD circuit 41 and the preamplifier 14 is not necessarily provided. Furthermore, the divider 42 may be included in the signal processing circuit 3.

The phase shift circuit 21 is an example of a first variable phase shift circuit. The phase shift circuit 21 is connected to the input end of the power amplifier 11 and is configured to vary the phase of a high frequency signal inputted to the phase shift circuit 21. The phase shift circuit 22 is an example of a second variable phase shift circuit. The phase shift circuit 22 is connected to the input end of the power amplifier 12 and is configured to vary the phase of a high frequency signal inputted to the phase shift circuit 22. The phase shift circuit 23 is connected to the input end of the power amplifier 13 and is configured to vary the phase of a high frequency signal inputted to the phase shift circuit 23.

The delay circuit 31 is an example of a first variable delay circuit. The delay circuit 31 is connected between the tracker circuit 2 and the power amplifier 11 and is configured to vary a delay amount of the variable power supply voltage Vcc outputted from the tracker circuit 2. The delay circuit 32 is an example of a second variable delay circuit. The delay circuit 32 is connected between the tracker circuit 2 and the power amplifier 12 and is configured to vary a delay amount of the variable power supply voltage Vcc outputted from the tracker circuit 2. The delay circuit 33 is connected between the tracker circuit 2 and the power amplifier 13 and is configured to vary a delay amount of the variable power supply voltage Vcc outputted from the tracker circuit 2.

With the arrangement described above, when the phase of a high frequency signal inputted to the amplifier circuit 1 is shifted by the phase shift circuits 21 to 23 and beamforming (adjustment of the beam angle of an output beam) of high frequency signals to be radiated from the antennas 4a to 4c is performed, timings at which the variable power supply voltage is supplied to the power amplifiers 11 to 13 can be adjusted by the delay circuits 31 to 33. Therefore, degradation of the EVM, ACLR, and the like of the high frequency signals outputted from the antennas 4a to 4c can be suppressed, and the linearity can be improved.

A delay amount that is varied by each of the delay circuits 31 to 33 corresponds to a phase delay Td (sec) or a group delay Tgd (sec) of the variable power supply voltage Vcc.

For example, the phase delay Td (ω) (sec) is expressed by Equation 1, where a phase shift amount between a high frequency signal inputted to each of the phase shift circuits 21 to 23 and a high frequency signal outputted from each of the phase shift circuits 21 to 23 is represented by φ(ω), the frequency of a high frequency signal is represented by f (=ω/2π), and ω represents an angular frequency.

$$Td ( ω ) = k 1 \frac{φ ( ω )}{2 π f} \qquad ( Equation 1 )$$

Furthermore, for example, the group delay Tgd (ω) (sec) is expressed by Equation 2.

$$Tgd ( ω ) = k 2 \frac{d φ ( ω )}{d ω} \qquad ( Equation 2 )$$

According to Equations 1 and 2, a delay amount of each of the delay circuits 31 to 33 increases as a phase shift amount φ increases.

A control circuit 50 is connected to the beam control terminals 120 to 140, the phase shift circuits 21 to 23, and the delay circuits 31 to 33. Based on the beam control signal s1, the control circuit 50 outputs a phase control signal s21 (first phase control signal) indicating a first phase shift amount to the phase shift circuit 21, and outputs a delay control signal s31 (first delay control signal) indicating a first delay amount corresponding to the first phase shift amount to the delay circuit 31. Furthermore, based on the beam control signal s2, the control circuit 50 outputs a phase control signal s22 (second phase control signal) indicating a second phase shift amount to the phase shift circuit 22, and outputs a delay control signal s32 (second delay control signal) indicating a second delay amount corresponding to the second phase shift amount to the delay circuit 32. Furthermore, based on the beam control signal s3, the control circuit 50 outputs a phase control signal s23 indicating a third phase shift amount to the phase shift circuit 23, and outputs a delay control signal s33 indicating a third delay amount corresponding to the third phase shift amount to the delay circuit 33.

The delay circuit 31 receives the delay control signal s31 from the control circuit 50 and adds the first delay amount corresponding to the first phase shift amount of the phase shift circuit 21 to the variable power supply voltage Vcc. The delay circuit 32 receives the delay control signal s32 from the control circuit 50 and adds the second delay amount corresponding to the second phase shift amount of the phase shift circuit 22 to the variable power supply voltage Vcc. The delay circuit 33 receives the delay control signal s33 from the control circuit 50 and adds the third delay amount corresponding to the third phase shift amount of the phase shift circuit 23 to the variable power supply voltage Vcc.

Accordingly, when beamforming of high frequency signals to be radiated from the antennas 4a to 4c is performed, the timings at which the variable power supply voltage is supplied to the power amplifiers 11 to 13 are adjusted in association with the phase shift amounts of the phase shift circuits 21 to 23. Therefore, degradation of the EVM, ACLR, and the like of the high frequency signals outputted from the antennas 4a to 4c can be suppressed, and the linearity can be improved.

Next, a circuit configuration of the delay circuits 31 to 33 will be illustrated.

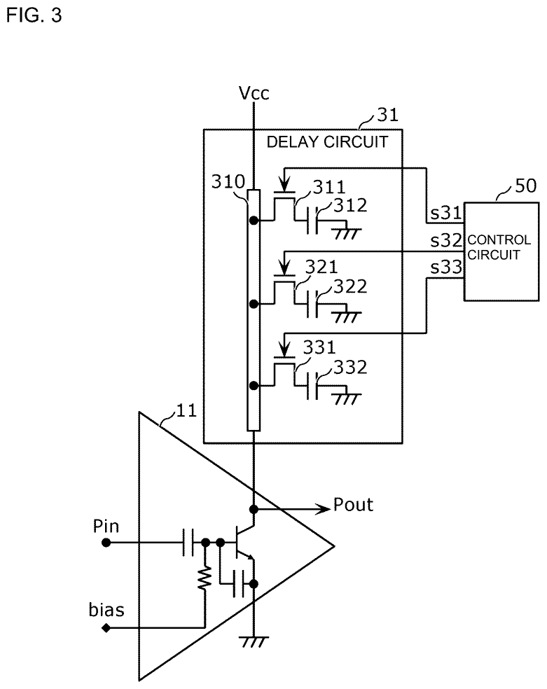

FIG. 3 is a circuit diagram illustrating an example of the delay circuit 31 and a peripheral circuit thereof in the embodiment. In FIG. 3, a circuit configuration and a connection arrangement of the delay circuit 31, the power amplifier 11, and the control circuit 50 are illustrated.

The power amplifier 11 includes a transistor, a resistor, and a capacitor. The transistor is, for example, an n-type bipolar transistor (amplifier element). The base of the transistor is connected to the input end (Pin) with a first capacitor interposed therebetween, the emitter of the transistor is connected to the ground, and the collector of the transistor is connected to the output end (Pout) and the delay circuit 31. Furthermore, a second capacitor is connected between the base and emitter of the transistor.

The delay circuit 31 includes a wire 310, switches 311, 321, and 331, and capacitors 312, 322, and 332. A series connection circuit including the switch 311 and the capacitor 312, a series connection circuit including the switch 321 and the capacitor 322, and a series connection circuit including the switch 331 and the capacitor 332 are each connected between the wire 310 and the ground. The series connection circuits are connected at different positions of the wire 310. The switch 311 is switched between electrical connection and electrical disconnection on the basis of the delay control signal s31 from the control circuit 50. The switch 321 is switched between electrical connection and electrical disconnection on the basis of the delay control signal s32 from the control circuit 50. The switch 331 is switched between electrical connection and electrical disconnection on the basis of the delay control signal s33 from the control circuit 50. That is, the delay control signals s31, s32, and s33 correspond to gate signals for the switches 311, 321, and 331, respectively. With the arrangement described above, by switching of the switches 311, 321, and 331, the position to which a capacitor is connected on the wire 310 can be varied, and a delay amount added to the variable power supply voltage Vcc transmitted through the wire 310 can thus be varied.

The circuit configuration of the delay circuit 31 is not limited to the circuit configuration example described above. In the case where the wire 310 is used, the circuit configuration only needs to be such that the electrical length of the wire 310 can be varied. An inductor may be used instead of the wire 310. Furthermore, in place of the three series connection circuits described above, variable capacitors such as digitally tunable capacitors (DTCs) may be used.

The delay circuits 32 and 33 each have a circuit configuration similar to that of the delay circuit 31.

### 2 Relationship Between Antenna Arrangement and Beam Radiation Direction

FIG. 4 is a diagram illustrating a relationship between an antenna arrangement and a beam radiation direction in the high frequency circuit 5 according to the embodiment. The antennas 4a to 4c configure an array antenna. The radiation surfaces of the antennas 4a to 4c are on one plane and are arranged in a straight line with a distance d therebetween on the plane. The amplitude and phase of excitation currents and voltages inputted to the antennas 4a to 4c are controlled, and high frequency signals radiated from the antennas 4a to 4c become a signal having a radiation directivity of a beam angle θ. The beam angle θ is defined as an angle formed by a normal direction of the radiation surface of each of the antennas 4a to 4c and the radiation direction of an output beam formed by the antennas 4a to 4c.

As illustrated in FIG. 4, in the case where high frequency signals outputted from the antennas 4a to 4c each have a plane wavefront, regarding the beam angle θ of a high frequency signal, the propagation path x of a high frequency signal (first high frequency signal) outputted from the antenna 4a is longer than that of a high frequency signal (second high frequency signal) outputted from the antenna 4b by d×sin θ. Furthermore, the propagation path x of the high frequency signal (second high frequency signal) outputted from the antenna 4b is longer than that of a high frequency signal (third high frequency signal) outputted from the antenna 4c by d×sin θ.

Therefore, in order to achieve the wavefront at the same phase between the first high frequency signal, the second high frequency signal, and the third high frequency signal, the phase of the second high frequency signal is delayed with respect to the phase of the first high frequency signal by a phase difference Δφ, and the phase of the third high frequency signal is delayed with respect to the phase of the second high frequency signal by the phase difference Δφ. The phase difference Δφ is expressed by Equation 3, where the wavelength of each of the first to third high frequency signals is represented by λ.

$$Δφ = \frac{2 π d \cdot sin θ}{λ} \qquad ( Equation 3 )$$

According to Equation 3, when the beam angle θ is equal to or more than 0 degrees and less than or equal to 90 degrees, the phase difference Δφ increases as the beam angle θ increases.

In order to satisfy the relationship represented by Equation 3, in the case where the first shift amount of the phase shift circuit 21 is set to 0, the second shift amount of the phase shift circuit 22 is represented by Δφ (delayed by Δφ) and the third shift amount of the phase shift circuit 23 is represented by 2×Δφ (delayed by 2×Δφ).

That is, the phase shift circuits 21 to 23 vary the phase shift amounts of the first to third high frequency signals on the basis of the radiation direction of the output beam formed by the antennas 4a to 4c.

### 3 Relationship Between Phase Shift Amount and Delay Amount

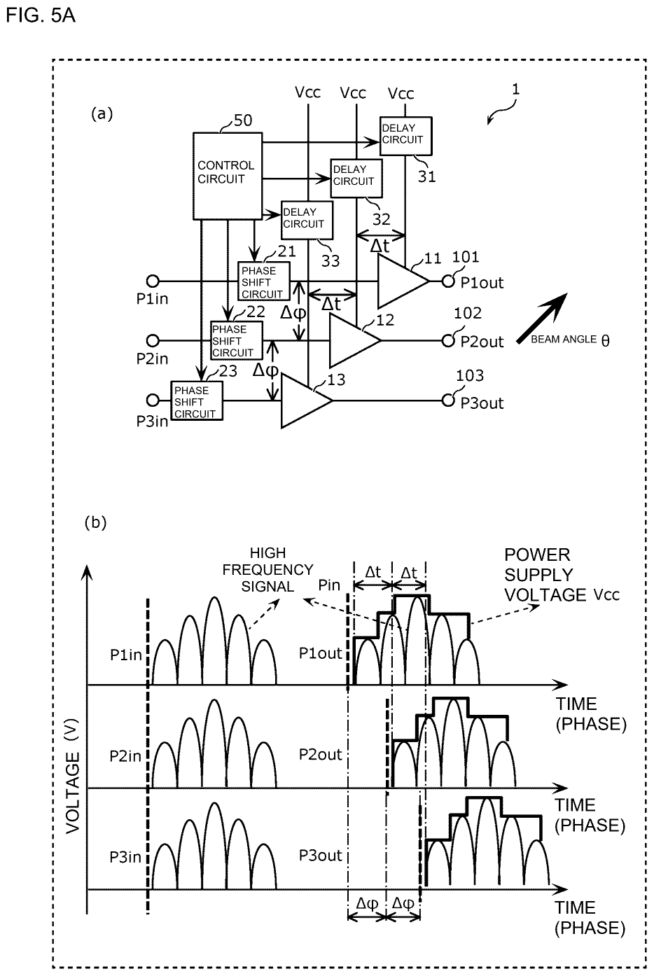

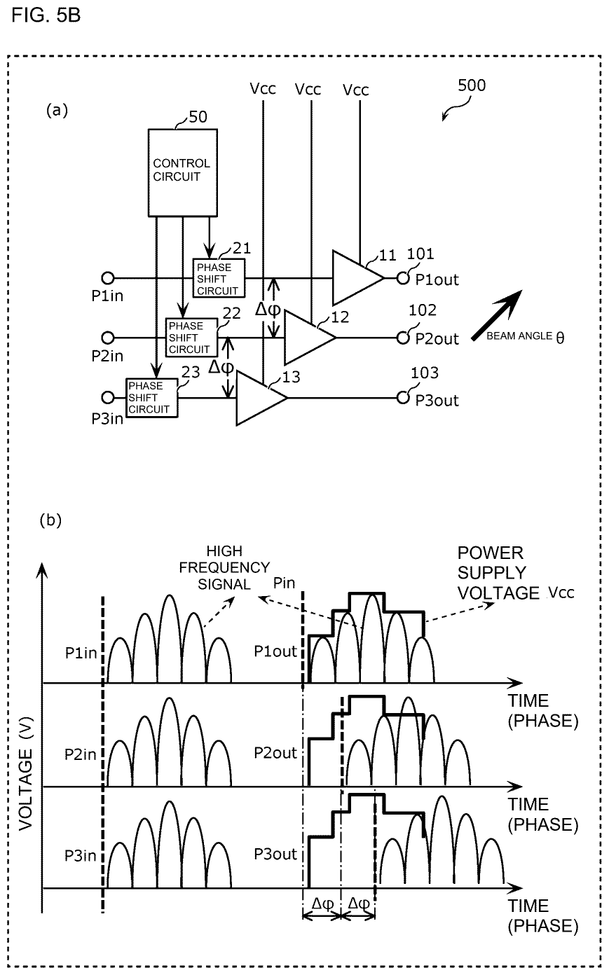

FIG. 5A includes diagrams illustrating relationships between high frequency signals and the variable power supply voltage Vcc inputted and outputted to and from the amplifier circuit 1 according to the embodiment. FIG. 5B includes diagrams illustrating relationships between high frequency signals and the variable power supply voltage Vcc inputted and outputted to and from an amplifier circuit 500 according to a comparative example.

Part (a) of FIG. 5A indicates a phase difference Δφ and a delay difference Δt for the case where high frequency signals of a beam angle θ are radiated in the amplifier circuit 1 according to the embodiment. Part (b) of FIG. 5A indicates relationships between high frequency signals P1in, P2in, and P3in inputted to the power amplifiers 11 to 13, high frequency signals P1out, P2out, and P3out outputted from the power amplifiers 11 to 13, and the variable power supply voltage Vcc supplied to the power amplifiers 11 to 13.

Furthermore, Part (a) of FIG. 5B indicates a phase difference Δφ for the case where high frequency signals of the beam angle θ are radiated in the amplifier circuit 500 according to the comparative example. Part (b) of FIG. 5B indicates relationships between the high frequency signals P1in, P2in, and P3in inputted to the power amplifiers 11 to 13, the high frequency signals P1out, P2out, and P3out outputted from the power amplifiers 11 to 13, and the variable power supply voltage Vcc supplied to the power amplifiers 11 to 13.

The amplifier circuit 500 according to the comparative example is different from the amplifier circuit 1 according to the embodiment only in that the delay circuits 31 to 33 are not provided.

As illustrated in FIG. 5B, in the amplifier circuit 500 according to the comparative example, when high frequency signals of the beam angle θ are radiated from the antennas 4a to 4c, the first to third phase shift amounts are generated in the phase shift circuits 21 to 23 so that the phase difference Δφ defined by Equation 3 can be satisfied. Thus, as illustrated in part (b) of FIG. 5B, the phase of the high frequency signal P2out is delayed with respect to the high frequency signal P1out by Δφ and the high frequency signal P3out is delayed with respect to the high frequency signal P2out by Δφ. However, since a delay amount is not generated for the variable power supply voltage Vcc, the variable power supply voltage Vcc is supplied to the power amplifiers 11 to 13 at the same timing. Therefore, variable power supply voltages Vcc that correspond to envelope values of the high frequency signals P2out and P3out are not supplied to the power amplifiers 12 and 13. Thus, the EVM, ACLR, and the like of the high frequency signals outputted from the amplifier circuit 500 are degraded, and the linearity of the high frequency signals is thus degraded.

In contrast, as illustrated in FIG. 5A, in the amplifier circuit 1 according to the embodiment, when high frequency signals of the beam angle θ are radiated from the antennas 4a to 4c, the first to third phase shift amounts are generated in the phase shift circuits 21 to 23 so that the phase difference Δφ defined by Equation 3 can be satisfied. In addition, the delay difference Δt corresponding to the phase difference Δφ is generated in each of the delay circuits 31 to 33. Specifically, in the case where a time difference obtained by subtracting the second delay amount generated by the delay circuit 32 from the third delay amount generated by the delay circuit 33 and a time difference obtained by subtracting the first delay amount generated by the delay circuit 31 from the second delay amount generated by the delay circuit 32 are each regarded as a delay difference Δt, the control circuit 50 performs control as described below.

That is, in order to achieve the beam angle θ1, when outputting the phase control signals s21, s22, and s23 with a phase difference of Δφ1, the control circuit 50 outputs the delay control signals s31, s32, and s33 with a delay difference of Δt1. Furthermore, in order to achieve the beam angle θ2, which is larger than the beam angle θ1, the control circuit 50 outputs the phase control signals s21, s22, and s23 with a phase difference of Δφ2, which is larger than Δφ1, and outputs the delay control signals s31, s32, and s33 with a delay difference of Δt2, which is larger than Δt1.

With the control by the control circuit 50 described above, in order to increase the beam angle θ from θ1 to θ2, the phase difference θφ is increased from Δφ1 to Δφ2 and the delay difference Δt is increased from Δt1 to Δt2. Furthermore, in order to decrease the beam angle θ from θ2 to θ1, the phase difference Δφ is decreased from Δφ2 to Δφ1 and the delay difference Δt is decreased from Δt2 to Δt1.

Accordingly, since the timings at which the variable power supply voltage Vcc is supplied to the power amplifiers 11 to 13 are in association with phase shift amounts of high frequency signals, variable power supply voltages Vcc corresponding to envelope values of the high frequency signals P1out, P2out, and P3out are supplied to the power amplifiers 11 to 13. Thus, degradation of the EVM, ACLR, and the like of the high frequency signals outputted from the amplifier circuit 1 can be suppressed, and degradation of the linearity can be suppressed.

### 4 Effects and Others

As described above, the high frequency circuit 5 according to an embodiment includes the power amplifiers 11 and 12 that amplify high frequency signals, the tracker circuit 2 that is configured to output a variable power supply voltage, the phase shift circuit 21 that is connected to the input end of the power amplifier 11 and is configured to vary a phase of a high frequency signal, the phase shift circuit 22 that is connected to the input end of the power amplifier 12 and is configured to vary a phase of a high frequency signal, the array antenna including the antenna 4a that is connected to the output end of the power amplifier 11 and the antenna 4b that is connected to the output end of the power amplifier 12, the delay circuit 31 that is connected between the tracker circuit 2 and the power amplifier 11 and is configured to vary a delay amount of the variable power supply voltage, and the delay circuit 32 that is connected between the tracker circuit 2 and the power amplifier 12 and is configured to vary a delay amount of the variable power supply voltage.

Accordingly, in beamforming of high frequency signals radiated from the antennas 4a and 4b, timings at which the variable power supply voltage is supplied to the power amplifiers 11 and 12 can be adjusted by the delay circuits 31 and 32. Therefore, degradation of the EVM, ACLR, and the like of the high frequency signals outputted from the antennas 4a and 4b can be suppressed, and linearity can be improved.

Furthermore, for example, in the high frequency circuit 5, the delay circuit 31 is configured to add a delay amount corresponding to a phase shift amount of the phase shift circuit 21 to the variable power supply voltage, and the delay circuit 32 is configured to add a delay amount corresponding to a phase shift amount of the phase shift circuit 22 to the variable power supply voltage.

Accordingly, in beamforming of high frequency signals radiated from the antennas 4a and 4b, timings at which the variable power supply voltage is supplied to the power amplifiers 11 and 12 can be adjusted in association with the phase shift amounts of the phase shift circuits 21 and 22. Therefore, degradation of the EVM, ACLR, and the like of the high frequency signals outputted from the antennas 4a and 4b can be suppressed, and linearity can be improved.

Furthermore, for example, the high frequency circuit 5 further includes the control circuit 50 that outputs the phase control signal s21 indicating the first phase shift amount to the phase shift circuit 21, outputs the phase control signal s22 indicating the second phase shift amount to the phase shift circuit 22, outputs the delay control signal s31 indicating the first delay amount corresponding to the first phase shift amount to the delay circuit 31, and outputs the delay control signal s32 indicating the second delay amount corresponding to the second phase shift amount to the delay circuit 32.

Furthermore, for example, in the high frequency circuit 5, in the case where an amount obtained by subtracting the first phase shift amount from the second phase shift amount is defined as a phase difference Δφ and a time obtained by subtracting the first delay amount from the second delay amount is defined as a delay difference Δt, when outputting the phase control signals s21 and s22 with a phase difference of Δφ1, the control circuit 50 outputs the delay control signals s31 and s32 with a delay difference of Δt1, and when outputting the phase control signals s21 and s22 with a phase difference of Δφ2, which is larger than Δφ1, the control circuit 50 outputs the delay control signals s31 and s32 with a delay difference of Δt2, which is larger than Δt1.

Accordingly, since the delay difference Δt increases as the phase difference Δφ increases, the phase difference Δφ and the delay difference Δt can be varied in association with each other.

Furthermore, for example, in the high frequency circuit 5, the phase shift circuits 21 and 22 vary, based on a radiation direction of an output beam formed by the antennas 4a and 4b, phase shift amounts of the high frequency signals.

Accordingly, by varying the phase shift amounts of the phase shift circuits 21 and 22, the beam angle θ of a high frequency signal can be adjusted.

Furthermore, for example, in the high frequency circuit 5, the tracker circuit 2 outputs, based on envelope values of the high frequency signals, a plurality of discrete variable power supply voltages.

Accordingly, the high frequency circuit 5 can amplify a high frequency signal using the digital ET. Furthermore, for example, in the high frequency circuit 5, the power amplifiers 11 and 12 are capable of amplifying high frequency signals in a millimeter-wave band or a sub-terahertz band.

Furthermore, the amplifier circuit 1 according to an embodiment includes the power amplifiers 11 and 12 to which a variable power supply voltage is supplied, the phase shift circuit 21 that is configured to vary, based on a first phase shift amount, a phase of a high frequency signal inputted to the power amplifier 11, the phase shift circuit 22 that is configured to vary, based on a second phase shift amount, a phase of a high frequency signal inputted to the power amplifier 12, an array antenna including the antenna 4a that radiates a high frequency signal outputted from the power amplifier 11 and the antenna 4b that radiates a high frequency signal outputted from the power amplifier 12, the delay circuit 31 that is configured to add a first delay amount corresponding to the first phase shift amount to the variable power supply voltage to be applied to the power amplifier 11, and the delay circuit 32 that is configured to add a second delay amount corresponding to the second phase shift amount to the variable power supply voltage to be applied to the power amplifier 12.

Accordingly, in beamforming of high frequency signals radiated from the antennas 4a and 4b, timings at which the variable power supply voltage is supplied to the power amplifiers 11 and 12 can be adjusted by the delay circuits 31 and 32 in association with the phase shift amounts of the phase shift circuits 21 and 22. Therefore, degradation of the EVM, ACLR, and the like of the high frequency signals outputted from the antennas 4a and 4b can be suppressed, and linearity can be improved.

Furthermore, for example, in the amplifier circuit 1, the delay circuits 31 and 32 each increase a delay difference Δt that is an amount obtained by subtracting the first delay amount from the second delay amount as a phase difference Δφ that is an amount obtained by subtracting the first phase shift amount from the second phase shift amount increases.

Accordingly, since the delay difference Δt increases as the phase difference Δφ increases, the phase difference Δφ and the delay difference Δt can be varied in association with each other.

Furthermore, the amplifier circuit 1 according to an embodiment includes the power amplifiers 11 and 12 that amplify high frequency signals, the power supply voltage terminal 110 that is an external connection terminal, the phase shift circuit 21 that is connected to the input end of the power amplifier 11 and is configured to vary a phase of a high frequency signal, the phase shift circuit 22 that is connected to the input end of the power amplifier 12 and is configured to vary a phase of a high frequency signal, the delay circuit 31 that is connected between the power supply voltage terminal 110 and the power amplifier 11 and is configured to vary a delay amount of a variable power supply voltage, and the delay circuit 32 that is connected between the power supply voltage terminal 110 and the power amplifier 12 and is configured to vary a delay amount of the variable power supply voltage.

Accordingly, in beamforming of high frequency signals outputted from the power amplifiers 11 and 12, timings at which the variable power supply voltage is supplied to the power amplifiers 11 and 12 can be adjusted by the delay circuits 31 and 32. Therefore, degradation of the EVM, ACLR, and the like of the high frequency signals outputted from the power amplifiers 11 and 12 can be suppressed, and linearity can be improved.

Furthermore, for example, in the amplifier circuit 1, the delay circuit 31 is configured to add a delay amount corresponding to a phase shift amount of the phase shift circuit 21 to the variable power supply voltage, and the delay circuit 32 is configured to add a delay amount corresponding to a phase shift amount of the phase shift circuit 22 to the variable power supply voltage.

Accordingly, in beamforming of high frequency signals outputted from the power amplifiers 11 and 12, timings at which the variable power supply voltage is supplied to the power amplifiers 11 and 12 can be adjusted in association with the phase shift amounts of the phase shift circuits 21 and 22. Therefore, degradation of the EVM, ACLR, and the like of the high frequency signals outputted from the power amplifiers 11 and 12 can be suppressed, and linearity can be improved.

Furthermore, for example, the amplifier circuit 1 further includes the control circuit 50 that outputs the phase control signal s21 indicating a first phase shift amount to the phase shift circuit 21, outputs the phase control signal s22 indicating a second phase shift amount to the phase shift circuit 22, outputs the delay control signal s31 indicating a first delay amount corresponding to the first phase shift amount to the delay circuit 31, and outputs the delay control signal s32 indicating a second delay amount corresponding to the second phase shift amount to the delay circuit 32.

Furthermore, for example, in the amplifier circuit 1, in the case where an amount obtained by subtracting the first phase shift amount from the second phase shift amount is defined as a phase difference Δφ and a time obtained by subtracting the first delay time from the second delay time is defined as a delay difference Δt, when outputting the phase control signals s21 and s22 with a phase difference of Δφ1, the control circuit 50 outputs the delay control signals s31 and s32 with a delay difference of Δt1, and when outputting the phase control signals s21 and s22 with a phase difference of Δφ2, which is larger than Δφ1, the control circuit 50 outputs the delay control signals s31 and s32 with a delay difference of Δt2, which is larger than Δt1.

Accordingly, since the delay difference Δt increases as the phase difference Δφ increases, the phase difference Δφ and the delay difference Δt can be varied in association with each other.

### Other Embodiments

A high frequency circuit and an amplifier circuit according to the present disclosure have been described above based on an embodiment. However, the high frequency circuit and the amplifier circuit according to the present disclosure are not limited to the embodiment described above. Other embodiments implemented by combining desired component elements in the embodiment described above, modifications obtained by making various changes conceivable by those skilled in the art to the embodiment described above without departing from the gist of the present disclosure, and various types of equipment including a high frequency circuit and an amplifier circuit described above are also included in the present disclosure.

For example, in a circuit configuration of a high frequency circuit and an amplifier circuit according to the embodiment described above, a circuit element, a wire, and the like may be inserted between circuit elements and paths connecting signal paths disclosed in the drawings.

Hereinafter, features of a high frequency circuit and an amplifier circuit described above based on each of the embodiments and modifications described above will be described below.

<1> A high frequency circuit comprising: a first power amplifier and a second power amplifier that amplify high frequency signals; a tracker circuit that is configured to output a variable power supply voltage; a first variable phase shift circuit that is connected to an input end of the first power amplifier and is configured to vary a phase of a high frequency signal; a second variable phase shift circuit that is connected to an input end of the second power amplifier and is configured to vary a phase of a high frequency signal; an array antenna including a first antenna that is connected to an output end of the first power amplifier and a second antenna that is connected to an output end of the second power amplifier; a first variable delay circuit that is connected between the tracker circuit and the first power amplifier and is configured to vary a delay amount of the variable power supply voltage; and a second variable delay circuit that is connected between the tracker circuit and the second power amplifier and is configured to vary a delay amount of the variable power supply voltage.

<2> The high frequency circuit according to <1>, wherein the first variable delay circuit is configured to add a delay amount corresponding to a phase shift amount of the first variable phase shift circuit to the variable power supply voltage, and wherein the second variable delay circuit is configured to add a delay amount corresponding to a phase shift amount of the second variable phase shift circuit to the variable power supply voltage.

<3> The high frequency circuit according to <1> or <2>, further comprising a control circuit that outputs a first phase control signal indicating a first phase shift amount to the first variable phase shift circuit, outputs a second phase control signal indicating a second phase shift amount to the second variable phase shift circuit, outputs a first delay control signal indicating a first delay amount corresponding to the first phase shift amount to the first variable delay circuit, and outputs a second delay control signal indicating a second delay amount corresponding to the second phase shift amount to the second variable delay circuit.

<4> The high frequency circuit according to <3>, wherein in a case where an amount obtained by subtracting the first phase shift amount from the second phase shift amount is defined as a phase difference Δφ and a time obtained by subtracting the first delay amount from the second delay amount is defined as a delay difference Δt, when outputting the first phase control signal and the second phase control signal with a phase difference of Δφ1, the control circuit outputs the first delay control signal and the second delay control signal with a delay difference of Δt1, and when outputting the first phase control signal and the second phase control signal with a phase difference of Δφ2, which is larger than Δφ1, the control circuit outputs the first delay control signal and the second delay control signal with a delay difference of Δt2, which is larger than Δt1.

<5> The high frequency circuit according to any one of <1> to <4>, wherein the first variable phase shift circuit and the second variable phase shift circuit vary, based on a radiation direction of an output beam formed by the first antenna and the second antenna, phase shift amounts of the high frequency signals.

<6> The high frequency circuit according to any one of <1> to <5>, wherein the tracker circuit outputs, based on envelope values of the high frequency signals, a plurality of discrete variable power supply voltages.

<7> The high frequency circuit according to any one of <1> to <6>, wherein the first power amplifier and the second power amplifier are capable of amplifying high frequency signals in a millimeter-wave band or a sub-terahertz band.

<8> A high frequency circuit comprising: a first power amplifier and a second power amplifier to which a variable power supply voltage is applied; first variable phase shift circuit that is configured to vary, based on a first phase shift amount, a phase of a high frequency signal input to the first power amplifier; a second variable phase shift circuit that is configured to vary, based on a second phase shift amount, a phase of a high frequency signal input to the second power amplifier; an array antenna including a first antenna that radiates a high frequency signal output from the first power amplifier and a second antenna that radiates a high frequency signal output from the second power amplifier; a first variable delay circuit that is configured to add a first delay amount corresponding to the first phase shift amount to the variable power supply voltage to be applied to the first power amplifier; and a second variable delay circuit that is configured to add a second delay amount corresponding to the second phase shift amount to the variable power supply voltage to be applied to the second power amplifier.

<9> The high frequency circuit according to <8>, wherein the first variable delay circuit and the second variable delay circuit each increase a delay difference Δt that is an amount obtained by subtracting the first delay amount from the second delay amount as a phase difference Δφ that is an amount obtained by subtracting the first phase shift amount from the second phase shift amount increases.

<10> An amplifier circuit comprising: a first power amplifier and a second power amplifier that amplify high frequency signals; an external connection terminal that receives a variable power supply voltage corresponding to a high frequency signal; a first variable phase shift circuit that is connected to an input end of the first power amplifier and is configured to vary a phase of a high frequency signal; a second variable phase shift circuit that is connected to an input end of the second power amplifier and is configured to vary a phase of a high frequency signal; a first variable delay circuit that is connected between the external connection terminal and the first power amplifier and is configured to vary a delay amount of the variable power supply voltage; and a second variable delay circuit that is connected between the external connection terminal and the second power amplifier and is configured to vary a delay amount of the variable power supply voltage.

<11> The amplifier circuit according to <10>, wherein the first variable delay circuit is configured to add a delay amount corresponding to a phase shift amount of the first variable phase shift circuit to the variable power supply voltage, and wherein the second variable delay circuit is configured to add a delay amount corresponding to a phase shift amount of the second variable phase shift circuit to the variable power supply voltage.

<12> The amplifier circuit according to <10> or <11>, further comprising: a control circuit that outputs a first phase control signal indicating a first phase shift amount to the first variable phase shift circuit, outputs a second phase control signal indicating a second phase shift amount to the second variable phase shift circuit, outputs a first delay control signal indicating a first delay amount corresponding to the first phase shift amount to the first variable delay circuit, and outputs a second delay control signal indicating a second delay amount corresponding to the second phase shift amount to the second variable delay circuit.

<13> The amplifier circuit according to <12>, wherein in a case where an amount obtained by subtracting the first phase shift amount from the second phase shift amount is defined as a phase difference Δφ and a time obtained by subtracting the first delay amount from the second delay amount is defined as a delay difference Δt, when outputting the first phase control signal and the second phase control signal with a phase difference of Δφ1, the control circuit outputs the first delay control signal and the second delay control signal with a delay difference of Δt1, and when outputting the first phase control signal and the second phase control signal with a phase difference of Δp2, which is larger than Δφ1, the control circuit outputs the first delay control signal and the second delay control signal with a delay difference of Δt2, which is larger than Δt1.

The present disclosure is widely usable as a high frequency circuit or a power amplifier circuit that is arranged in a front end section supporting multiple bands for communication equipment such as a mobile phone.
1, 500 amplifier circuit
2 tracker circuit
3 signal processing circuit
4a, 4b, 4c antenna
5 high frequency circuit
11, 12, 13 power amplifier
14 preamplifier
21, 22, 23 phase shift circuit
31, 32, 33 delay circuit
41 DPD circuit
42 divider
50 control circuit
60 discrete voltage generation circuit
70 voltage selection circuit
80 digital control circuit
100 signal input terminal
101, 102, 103 antenna connection terminal
110 power supply voltage terminal
120, 130, 140 beam control terminal
310 wire
311, 321, 331 switch
312, 322, 332 capacitor

1. A high frequency circuit comprising:
a first power amplifier and a second power amplifier that are each configured to amplify high frequency signals;
a tracker circuit that is configured to output a variable power supply voltage;
a first variable phase shift circuit that is connected to an input end of the first power amplifier and that is configured to vary a phase of a first high frequency signal;
a second variable phase shift circuit that is connected to an input end of the second power amplifier and that is configured to vary a phase of a second high frequency signal;
an array antenna comprising a first antenna that is connected to an output end of the first power amplifier, and a second antenna that is connected to an output end of the second power amplifier;
a first variable delay circuit that is connected between the tracker circuit and the first power amplifier, and that is configured to vary a delay amount of the variable power supply voltage; and
a second variable delay circuit that is connected between the tracker circuit and the second power amplifier, and that is configured to vary a delay amount of the variable power supply voltage.

2. The high frequency circuit according to claim 1,
wherein the first variable delay circuit is configured to add a delay amount corresponding to a phase shift amount of the first variable phase shift circuit to the variable power supply voltage, and
wherein the second variable delay circuit is configured to add a delay amount corresponding to a phase shift amount of the second variable phase shift circuit to the variable power supply voltage.

3. The high frequency circuit according to claim 1, further comprising:
a control circuit configured to output a first phase control signal indicating a first phase shift amount to the first variable phase shift circuit, to output a second phase control signal indicating a second phase shift amount to the second variable phase shift circuit, to output a first delay control signal indicating a first delay amount corresponding to the first phase shift amount to the first variable delay circuit, and to output a second delay control signal indicating a second delay amount corresponding to the second phase shift amount to the second variable delay circuit.

4. The high frequency circuit according to claim 3,
when outputting the first phase control signal and the second phase control signal with a phase difference of Δφ1, the control circuit is configured to output the first delay control signal and the second delay control signal with a delay difference of Δt1, and
when outputting the first phase control signal and the second phase control signal with a phase difference of Δφ2, which is larger than Δφ1, the control circuit is configured to output the first delay control signal and the second delay control signal with a delay difference of Δt2, which is larger than Δt1,
where an amount obtained by subtracting the first phase shift amount from the second phase shift amount is a phase difference Δφ and an amount obtained by subtracting the first delay amount from the second delay amount is a delay difference Δt.

5. The high frequency circuit according to claim 1, wherein the first variable phase shift circuit and the second variable phase shift circuit are configured to vary phase shift amounts of the first and second high frequency signals based on a radiation direction of an output beam formed by the first antenna and the second antenna.

6. The high frequency circuit according to claim 1, wherein the tracker circuit is configured to output a plurality of discrete variable power supply voltages based on envelope values of the first and second high frequency signals.

7. The high frequency circuit according to claim 1, wherein the first power amplifier and the second power amplifier are configured to amplify high frequency signals in a millimeter-wave band or a sub-terahertz band.

8. A high frequency circuit comprising:
a first power amplifier and a second power amplifier to which a variable power supply voltage is applied;
a first variable phase shift circuit that is configured to vary, based on a first phase shift amount, a phase of a high frequency signal input to the first power amplifier;
a second variable phase shift circuit that is configured to vary, based on a second phase shift amount, a phase of a high frequency signal input to the second power amplifier;
an array antenna comprising a first antenna that is configured to radiate a first high frequency signal output from the first power amplifier and a second antenna that is configured to radiate a second high frequency signal output from the second power amplifier;
a first variable delay circuit that is configured to add a first delay amount corresponding to the first phase shift amount to the variable power supply voltage applied to the first power amplifier; and
a second variable delay circuit that is configured to add a second delay amount corresponding to the second phase shift amount to the variable power supply voltage applied to the second power amplifier.

9. The high frequency circuit according to claim 8, wherein the first variable delay circuit and the second variable delay circuit are each configured to increase a delay difference Δt as a phase difference Δφ, the delay difference Δt being an amount obtained by subtracting the first delay amount from the second delay amount, and the phase difference Δφ being an amount obtained by subtracting the first phase shift amount from the second phase shift amount increases.

10. An amplifier circuit comprising:
a first power amplifier and a second power amplifier that are each configured to amplify high frequency signals;
an external connection terminal configured to receive a variable power supply voltage corresponding to a high frequency signal;
a first variable phase shift circuit that is connected to an input end of the first power amplifier and that is configured to vary a phase of a first high frequency signal;
a second variable phase shift circuit that is connected to an input end of the second power amplifier and that is configured to vary a phase of a second high frequency signal;
a first variable delay circuit that is connected between the external connection terminal and the first power amplifier, and that is configured to vary a delay time of the variable power supply voltage; and
a second variable delay circuit that is connected between the external connection terminal and the second power amplifier, and that is configured to vary a delay time of the variable power supply voltage.

11. The amplifier circuit according to claim 10,
wherein the first variable delay circuit is configured to add a delay amount corresponding to a phase shift amount of the first variable phase shift circuit to the variable power supply voltage, and
wherein the second variable delay circuit is configured to add a delay amount corresponding to a phase shift amount of the second variable phase shift circuit to the variable power supply voltage.

12. The amplifier circuit according to claim 10, further comprising:
a control circuit configured to output a first phase control signal indicating a first phase shift amount to the first variable phase shift circuit, to output a second phase control signal indicating a second phase shift amount to the second variable phase shift circuit, to output a first delay control signal indicating a first delay amount corresponding to the first phase shift amount to the first variable delay circuit, and to output a second delay control signal indicating a second delay amount corresponding to the second phase shift amount to the second variable delay circuit.

13. The amplifier circuit according to claim 12,
when outputting the first phase control signal and the second phase control signal with a phase difference of Δφ1, the control circuit is configured to output the first delay control signal and the second delay control signal with a delay difference of Δt1, and
when outputting the first phase control signal and the second phase control signal with a phase difference of Δφ2, which is larger than Δφ1, the control circuit is configured to output the first delay control signal and the second delay control signal with a delay difference of Δt2, which is larger than Δt1,
where an amount obtained by subtracting the first phase shift amount from the second phase shift amount is a phase difference Δφ and an amount obtained by subtracting the first delay amount from the second delay amount is a delay difference Δt.
